(19) United States
(12) Patent Application Publication
(10) Pub. No.: US 2025/0280580 A1
(43) Pub. Date: Sep. 4, 2025

(54) SEMICONDUCTOR SEED LAYER ON SOURCE/DRAIN DIELECTRIC STRUCTURES

(71) Applicant: Taiwan Semiconductor Manufacturing Company, Ltd., Hsinchu (TW)

(72) Inventors: Ting-Hsiang CHANG, New Taipei (TW); Chung-Ting KO, Kaohsiung City (TW); Shu Ling LIAO, Taichung City (TW); Yu-Ru LIN, Hsinchu (TW); Sung-En LIN, Hsinchu County (TW); Tai-Chun HUANG, Hsin-Chu City (TW); Tze-Liang LEE, Hsinchu (TW)

(73) Assignee: Taiwan Semiconductor Manufacturing Company, Ltd., Hsinchu (TW)

(21) Appl. No.: 18/771,644

(22) Filed: Jul. 12, 2024

Related U.S. Application Data
(60) Provisional application No. 63/560,440, filed on Mar. 1, 2024.

(51) Int. Cl. H01L 29/26; H01L 27/088; H01L 29/06; H01L 29/417; H01L 29/423; H01L 29/66; H01L 29/775; H01L 29/786

(52) U.S. Cl. CPC H10D 62/80; H10D 30/014; H10D 62/116; H10D 62/402; H10D 64/258; H10D 30/43; H10D 30/6735; H10D 30/6757; H10D 62/121; H10D 84/83

(57) ABSTRACT

The present disclosure describes a semiconductor device having a semiconductor seed layer on a S/D dielectric structure. The semiconductor structure includes a channel structure on a substrate, a gate structure wrapped around the channel structure, an inner spacer adjacent to end portions of the gate structure and the channel structure, a dielectric structure on the substrate and adjacent to the inner spacer, a non-crystalline semiconductor material on the dielectric structure, and an epitaxial structure on top surfaces of the non-crystalline semiconductor material and the dielectric structure.

### CROSS-REFERENCE TO RELATED APPLICATION

This application claims the benefit of U.S. Provisional Patent Application No. 63/560,440, titled “Silicon Seed Layer on Embedded Dielectric for Bottom-Up Epitaxial Growth without DC Penalty,” filed Mar. 1, 2024, the disclosure of which is incorporated by reference in its entirety.

### BACKGROUND

With advances in semiconductor technology, there has been increasing demand for higher storage capacity, faster processing systems, higher performance, and lower costs. To meet these demands, the semiconductor industry continues to scale down the dimensions of semiconductor devices, such as metal oxide semiconductor field effect transistors (MOSFETs), including planar MOSFETs and fin field effect transistors (finFETs). Such scaling down has increased the complexity of semiconductor manufacturing processes and increased the difficulty of process control in the semiconductor devices.

### BRIEF DESCRIPTION OF THE DRAWINGS

Aspects of the present disclosure are best understood from the following detailed description when read with the accompanying figures.

FIG. 1 illustrates an isometric view of a semiconductor device having a semiconductor seed layer on source/drain dielectric structures, in accordance with some embodiments.

FIG. 2 illustrates a cross-sectional view of a semiconductor device having a semiconductor seed layer on source/drain dielectric structures, in accordance with some embodiments.

FIG. 3 is a flow diagram of a method for fabricating a semiconductor device having a semiconductor seed layer on source/drain dielectric structures, in accordance with some embodiments.

FIGS. 4-12 illustrate cross-sectional views of a semiconductor device having a semiconductor seed layer on source/drain dielectric structures at various stages of its fabrication, in accordance with some embodiments.

Illustrative embodiments will now be described with reference to the accompanying drawings. In the drawings, like reference numerals generally indicate identical, functionally similar, and/or structurally similar elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over a second feature in the description that follows may include embodiments in which the first and second features are formed in direct contact, and may also include embodiments in which additional features may be formed between the first and second features, such that the first and second features may not be in direct contact. As used herein, the formation of a first feature on a second feature means the first feature is formed in direct contact with the second feature. In addition, the present disclosure may repeat reference numerals and/or letters in the various examples. This repetition does not in itself dictate a relationship between the various embodiments and/or configurations discussed.

Further, spatially relative terms, such as “beneath,” “below,” “lower,” “above,” “upper,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It is noted that references in the specification to “one embodiment,” “an embodiment,” “an example embodiment,” “exemplary,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to effect such feature, structure or characteristic in connection with other embodiments whether or not explicitly described.

It is to be understood that the phraseology or terminology herein is for the purpose of description and not of limitation, such that the terminology or phraseology of the present specification is to be interpreted by those skilled in relevant art(s) in light of the teachings herein.

In some embodiments, the terms “about” and “substantially” can indicate a value of a given quantity that varies within 20% of the value (e.g., ±1%, ±2%, ±3%, ±4%, ±5%, ±10%, ±20% of the value). These values are merely examples and are not intended to be limiting. The terms “about” and “substantially” can refer to a percentage of the values as interpreted by those skilled in relevant art(s) in light of the teachings herein.

With increasing demand for lower power consumption, higher performance, and smaller semiconductor devices, dimensions of semiconductor devices continue to scale down. The continuous scaling down of device dimensions and the increasing demand for device performance may require various process and material improvements, which can have multiple challenges. For example, nanostructure transistors can provide improved device performance with a channel in a stacked nanosheet/nanowire configuration. The nanostructure transistors can include finFETs, gate-all-around field effect transistors (GAA FETs), nanosheet transistors, nanowire transistors, multi-bridge channel transistors, nano-ribbon transistors, and other similar structured transistors. A source/drain (S/D) dielectric structure can be formed on the substrate between the stacked nanosheets/nanowires to reduce the leakage current through the substrate parasitic channel below the stacked nanosheets/nanowires. However, the subsequently grown S/D structures can include an amorphous portion on the S/D dielectric structure and a crystalline portion on the amorphous portion. The amorphous portion can have a higher resistance and a lower carrier mobility than the crystalline portion. Additionally, the amorphous portion can lead to a loss of strain on the channel of the nanostructure transistors. As a result, the direct current (DC) device performance of the nanostructure transistors may be reduced.

Various embodiments in the present disclosure provide methods for forming a semiconductor seed layer on S/D dielectric structures in a semiconductor device (e.g., a nanostructure transistor) and/or other semiconductor devices in an integrated circuit (IC). In some embodiments, a channel structure stacked on a fin structure can be formed on a substrate. A recess can be formed in the fin structure adjacent to the channel structure. A S/D dielectric structure and a semiconductor seed layer can be formed in the recess. The S/D dielectric structure and the semiconductor seed layer can be below a bottom surface of the channel structure. An epitaxial structure can be formed on top surfaces of the S/D dielectric structure and the semiconductor seed layer. The epitaxial structure can include a non-crystalline portion and a crystalline portion. The crystalline portion can be in contact with the channel structure and the non-crystalline portion can be below the bottom surface of the channel structure. With the S/D dielectric structure, the semiconductor seed layer, and the non-crystalline portion of the epitaxial structure below the bottom surface of the channel structure, resistance between the epitaxial structure and the channel structure can be reduced. The carrier mobility in the epitaxial structure can be increased. The strain on the channel structure exerted by the epitaxial structure can be increased. Accordingly, the DC device performance of the semiconductor device can be improved.

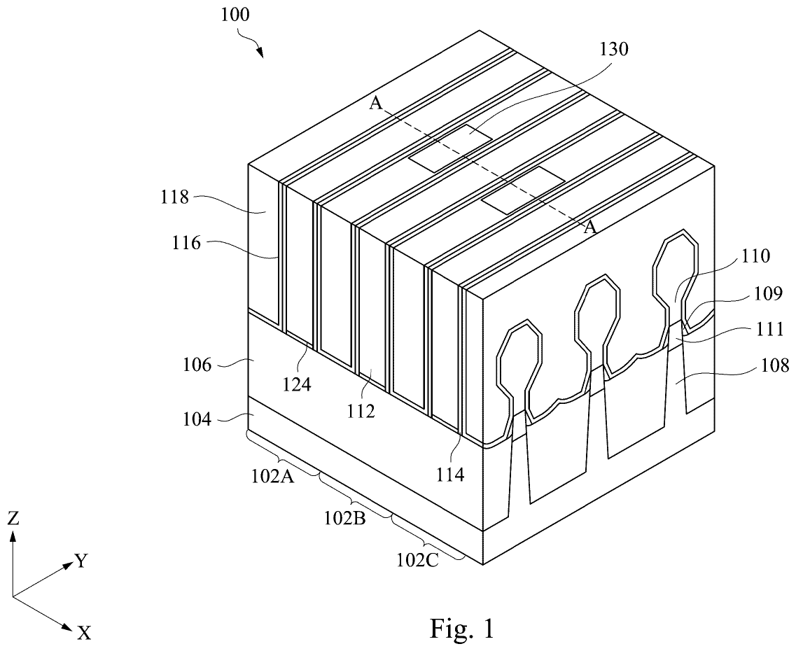

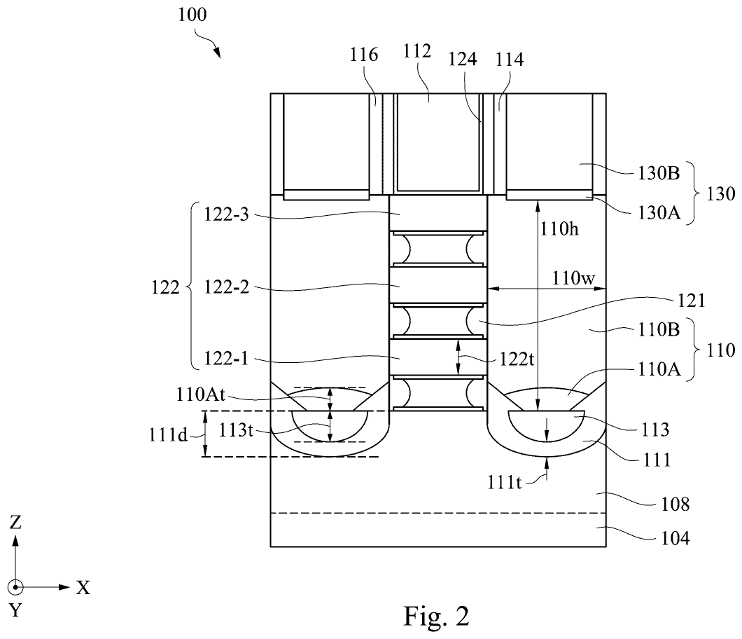

FIG. 1 illustrates an isometric view of a semiconductor device 100 having a semiconductor seed layer on a S/D dielectric structure, in accordance with some embodiments. FIG. 2 illustrates a partial cross-sectional view of semiconductor device 100 having a semiconductor seed layer on S/D dielectric structures across line A-A shown in FIG. 1, in accordance with some embodiments.

In some embodiments, semiconductor device 100 can include transistors 102A-102C, as shown in FIG. 1. In some embodiments, transistors 102A-102C can include nanostructure transistors. The nanostructure transistors can include finFETs, GAA FETs, nanosheet transistors, nanowire transistors, multi-bridge channel transistors, nano-ribbon transistors, and other similar structured transistors. The nanostructure transistors can provide a channel in a stacked nanosheet/nanowire configuration. In some embodiments, transistors 102A-102C can be n-type field-effect transistors (NFETs). In some embodiments, transistors 102A-102C can be p-type field-effect transistors (PFETs). In some embodiments, any of transistors 102A-102C can be an NFET or a PFET. Though FIG. 1 shows three transistors, semiconductor device 100 can have any number of transistors. In addition, semiconductor device 100 can be incorporated into an IC through the use of other structural components, such as conductive vias, conductive lines, dielectric layers, passivation layers, and interconnects, which are not shown for simplicity. The discussion of elements of transistors 102A-102C with the same annotations applies to each other, unless mentioned otherwise. And like reference numerals generally indicate identical, functionally similar, and/or structurally similar elements.

Referring to FIGS. 1 and 2, semiconductor device 100 having transistors 102A-102C can be formed on a substrate 104 and can be isolated by shallow trench isolation (STI) regions 106. Each of transistors 102A-102C can include fin structures 108, sidewall spacers 109, gate dielectric layer 124, gate structures 112, gate spacers 114, inner spacers 121, S/D dielectric structures 111, semiconductor seed layer 113, S/D structures 110, etch stop layer (ESL) 116, interlayer dielectric (ILD) layer 118, and S/D contact structures 130. In some embodiments, as shown in FIG. 2, transistors 102A-102C can have nanostructures 122-1, 122-2, and 122-3 (collectively referred to as “nanostructures 122”) on fin structures 108.

Referring to FIGS. 1 and 2, substrate 104 can include a semiconductor material, such as silicon. In some embodiments, substrate 104 includes a crystalline silicon substrate (e.g., silicon wafer). In some embodiments, substrate 104 includes (i) an elementary semiconductor, such as germanium; (ii) a compound semiconductor including silicon carbide, gallium arsenide, gallium phosphide, indium phosphide, indium arsenide, and/or indium antimonide; (iii) an alloy semiconductor including silicon germanium carbide, silicon germanium, gallium arsenic phosphide, and/or aluminum gallium arsenide; or (iv) a combination thereof. Further, substrate 104 can be doped depending on design requirements (e.g., p-type substrate or n-type substrate). In some embodiments, substrate 104 can be doped with p-type dopants (e.g., boron, indium, aluminum, or gallium) or n-type dopants (e.g., phosphorus or arsenic).

STI regions 106 can provide electrical isolation between transistors 102A-102C and from neighboring transistors (not shown) on substrate 104 and/or neighboring active and passive elements (not shown) integrated with or deposited on substrate 104. STI regions 106 can be made of a dielectric material. In some embodiments, STI regions 106 can include silicon oxide, silicon nitride, silicon oxynitride, fluorine-doped silicate glass (FSG), a low-k dielectric material, and/or other suitable insulating materials. In some embodiments, STI regions 106 can include a multi-layered structure.

Referring to FIGS. 1 and 2, nanostructures 122 and fin structures 108 can be formed on patterned portions of substrate 104. Embodiments of the nanostructures and fin structures disclosed herein may be patterned by any suitable method. For example, the nanostructures and fin structures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the nanostructures and fin structures.

As shown in FIGS. 1 and 2, nanostructures 122 and fin structures 108 can extend along an X-axis for transistors 102A-102C. In some embodiments, nanostructures 122 and fin structures 108 can be disposed on substrate 104. Nanostructures 122 can include a stack of nanostructures 122-1, 122-2, and 122-3, which can be in the form of nanosheets, nanowires, or nano-ribbons. Each of nanostructures 122 can act as a channel structure and form a channel region underlying gate structures 112 of transistors 102A-102C. In some embodiments, nanostructures 122 and fin structures 108 can include semiconductor materials similar to or different from substrate 104. In some embodiments, nanostructures 122 and fin structures 108 can include silicon. In some embodiments, nanostructures 122 and fin structures 108 can include silicon germanium. The semiconductor materials of nanostructures 122 and fin structures 108 can be undoped or can be in-situ doped during their formation process. In some embodiments, as shown in FIG. 2, nanostructures 122 under gate structures 112 can form channel regions of semiconductor device 100 and represent current carrying channel structures of semiconductor device 100. Though three layers of nanostructures 122 are shown in FIG. 2, transistors 102A-102C can have any number of nanostructures 122. In some embodiments, nanostructures 122 can have a thickness 122t along a Z-axis ranging from about 3 nm to about 8 nm. In some embodiments, a spacing between adjacent nanostructures 122 along a Z-axis can range from about 5 nm to about 12 nm.

Referring to FIGS. 1 and 2, gate dielectric layer 124 can be formed on nanostructures 122, fin structures 108, and STI regions 106. In some embodiments, gate dielectric layer 124 can be multi-layered structures and can include an interfacial layer and a high-k dielectric layer. In some embodiments, gate dielectric layer 124 can include no interfacial layer and the high-k dielectric layer can be in direct contact with nanostructures 122. In some embodiments, the interfacial layer can include silicon oxide formed by a deposition process or an oxidation process. In some embodiments, the interfacial layer can have a thickness ranging from about 0.1 nm to about 1.5 nm. In some embodiments, the high-k dielectric layer can include hafnium oxide, zirconium oxide, or other suitable high-k dielectric materials.

In some embodiments, as shown in FIGS. 1 and 2, gate structures 112 can be disposed on gate dielectric layer 124. In some embodiments, gate structures 112 can include one or more work function metal layers and a metal fill. The one or more work function metal layers can include work function metals to tune the threshold voltage (Vₜ) of transistors 102A-102C. In some embodiments, gate structures 112 for NFET and PFET devices can have substantially the same work-function metal. In some embodiments, gate structures 112 for NFET and PFET devices can have different work-function metals. In some embodiments, as shown in FIG. 2, each of nanostructures 122 can be wrapped around by gate structures 112, for which gate structures 112 can be referred to as “gate-all-around (GAA) structures” and transistors 102A-102C can also be referred to as “GAA FETs 102A-102C.” The one or more work function metal layers can wrap around nanostructures 122 and can include work function metals to tune the Vₜ of transistors 102A-102C. In some embodiments, transistors 102A-102C can include any number of work function metal layers for Vₜ tuning (e.g., ultra-low Vₜ, low Vₜ, and standard Vₜ).

In some embodiments, NFETs 102A-102C can include n-type work function metal layers. The n-type work function metal layers can include aluminum, titanium aluminum, titanium aluminum carbon, tantalum aluminum, tantalum aluminum carbon, tantalum silicon carbide, hafnium carbide, silicon, titanium nitride, titanium silicon nitride, or other suitable work function metals. In some embodiments, PFETs 102A-102C can include p-type work function metal layers. The p-type work function metal layers can include titanium nitride, titanium silicon nitride, tantalum nitride, tungsten carbon nitride, tungsten, molybdenum, or other suitable work function metals. In some embodiments, the work function metal layers can include a single metal layer or a stack of metal layers. The stack of metal layers can include work function metals having work-function values equal to or different from each other. In some embodiments, the metal fill can include titanium, tantalum, aluminum, cobalt, tungsten, nickel, ruthenium, or other suitable conductive materials.

Referring to FIGS. 1 and 2, gate spacers 114 can be disposed on sidewalls of gate structures 112 and in contact with gate dielectric layer 124, according to some embodiments. Sidewall spacers 109 can be disposed on sidewalls of fin structures 108. Inner spacers 121 can be disposed adjacent to end portions of nanostructures 122 and between S/D structures 110 and gate structures 112. Gate spacers 114, sidewall spacers 109, and inner spacers 121 can include insulating materials, such as silicon oxide, silicon nitride, silicon oxynitride, silicon carbonitride, silicon oxycarbide, silicon oxycarbonitride, aluminum oxide, a low-k material, and a combination thereof. In some embodiments, gate spacers 114, sidewall spacers 109, and inner spacers 121 can include the same insulating material. In some embodiments, gate spacers 114, sidewall spacers 109, and inner spacers 121 can include different insulating materials. In some embodiments, gate spacers 114, sidewall spacers 109, and inner spacers 121 can include a single layer or a stack of insulating layers. In some embodiments, gate spacers 114, sidewall spacers 109, and inner spacers 121 can have a low-k material with a dielectric constant less than about 3.9 (e.g., about 3.5, about 3.0, or about 2.8).

In some embodiments, S/D dielectric structures 111 can be disposed on fin structures 108. In some embodiments, S/D dielectric structures 111 can include aluminum oxide (AlOₓ), silicon carbide (SiCₓ), silicon nitride (SiNₓ), silicon carbonitride (SiCₓN₁₋ₓ), silicon oxycarbonitride (SiO_{y}CₓN_{1-x-y}), a low-k material, or a combination thereof. In some embodiments, S/D dielectric structures 111 can reduce leakage current through fin structures 108 and improve device performance. In some embodiments, S/D dielectric structures 111 can have a thickness 111t ranging from about 3 nm to about 5 nm. A ratio of thickness 111t to thickness 122t can range from about 0.2 to about 0.8. If thickness 111t is less than about 3 nm or the ratio is less than about 0.2, S/D dielectric structures 111 may not reduce leakage current in semiconductor device 100 and device performance may not be improved. If thickness 111t is greater than about 5 nm or the ratio is greater than about 0.8, S/D dielectric structures 111 may be in contact with nanostructures 122, which can lead to reduced device current and degraded device performance.

In some embodiments, as shown in FIGS. 1 and 2, S/D dielectric structures 111 can extend into fin structures 108. In some embodiments, S/D dielectric structures 111 can extend a distance 111d below a bottom surface of gate structures 112. In some embodiments, distance 111d can range from about 4 nm to about 12 nm. A ratio between distance 111d to thickness 122t can range from about 1 to about 2. If distance 111d is less than about 4 nm or the ratio is less than about 1, device current between nanostructures 122 and S/D structures 110 can be reduced and device performance can be degraded. If distance 111d is greater than about 12 nm, or the ratio is greater than about 2, device performance may not be further improved while manufacturing cost may increase.

In some embodiments, S/D dielectric structures 111 can be below a bottom surface of bottom nanostructures 122-1 to avoid contact between S/D dielectric structures 111 and nanostructures 122. If S/D dielectric structures 111 are in contact with nanostructures 122, device current between nanostructures 122 and S/D structures 110 can be reduced and device performance can be degraded. In some embodiments, as shown in FIG. 2, S/D dielectric structures 111 can have a “U” shape and end portions of S/D dielectric structures 111 can cover inner spacers 121 below bottom nanostructures 122-1. In some embodiments, as shown in FIG. 2, the end portions of S/D dielectric structures 111 can have sloped top surfaces with inner edges of the end portions lower than the outer edges of the end portions. In some embodiments, a height difference between the inner edges and the outer edges of the end portions of S/D dielectric structures 111 can range from about 5 nm to about 12 nm. In some embodiments, with end portions of S/D dielectric structures 111 covering inner spacers 121, the parasitic capacitance between S/D structures 110 and gate structures 112 can be reduced and device performance can be improved.

In some embodiments, as shown in FIG. 2, semiconductor seed layer 113 can be disposed on S/D dielectric structures 111 and surrounded by S/D dielectric structures 111. In some embodiments, semiconductor seed layer 113 can include non-crystalline silicon, non-crystalline silicon germanium, or other suitable non-crystalline semiconductor materials. In some embodiments, semiconductor seed layer 113 can include a non-crystalline semiconductor material, such as amorphous silicon or poly-crystalline silicon. In some embodiments, semiconductor seed layer 113 can act as a seed layer for subsequent growth of S/D structures 110. Semiconductor seed layer 113 can facilitate the growth of S/D structures 110 without forming voids between S/D structures 110 and S/D dielectric structures 111. In some embodiments, semiconductor seed layer 113 can be below the bottom surface of bottom nanostructures 122-1. If semiconductor seed layer 113 is above the bottom surface of bottom nanostructures 122-1, nanostructures 122 may be in contact with S/D dielectric structures 111 and/or semiconductor seed layer 113, device current between nanostructures 122 and S/D structures 110 can be reduced and device performance can be degraded.

In some embodiments, semiconductor seed layer 113 can have a thickness 113tranging from about 1 nm to about 7.5 nm. A ratio of thickness 113t to thickness 122t can range from about 0.1 to about 0.9. If thickness 113t is less than about 1 nm or the ratio is less than about 0.1, voids may be formed between S/D dielectric structures 111 and S/D structures 110 and the device performance may be degraded. If thickness 113t is greater than about 7.5 nm or the ratio is greater about 0.9, nanostructures 122 may be in contact with non-crystalline semiconductor materials in semiconductor seed layer 113 and/or S/D structures 110 and the device current may be reduced.

Referring to FIGS. 1 and 2, S/D structures 110 can be disposed on top surfaces of semiconductor seed layer 113 and S/D dielectric structures 111. S/D structures 110 can function as S/D regions of transistors 102A-102C. In some embodiments, S/D structures 110 can have any geometric shape, such as a polygon, a cone, a diamond, an ellipsis, and a circle. In some embodiments, S/D structures 110 can include an epitaxially-grown semiconductor material, such as silicon (e.g., the same material as substrate 104). In some embodiments, S/D structures 110 can include an epitaxially-grown semiconductor material different from the material of substrate 104, such as silicon germanium, and can impart a strain on the channel regions of nanostructures 122 under gate structures 112. Since the lattice constant of such epitaxially-grown semiconductor material is different from the material of substrate 104, the channel regions of nanostructures 122 are strained to increase carrier mobility in the channel regions of semiconductor device 100. The epitaxially-grown semiconductor material can include: (i) a semiconductor material, such as germanium and silicon; (ii) a compound semiconductor material, such as gallium arsenide and aluminum gallium arsenide; or (iii) a semiconductor alloy, such as silicon germanium and gallium arsenide phosphide.

In some embodiments, S/D structures 110 can include silicon and can be in-situ doped during an epitaxial growth process using n-type dopants, such as phosphorus and arsenic. For n-type in-situ doping, n-type doping precursors, such as phosphine, arsine, and other n-type doping precursors, can be used. In some embodiments, S/D structures 110 can include silicon, silicon germanium, germanium, or III-V materials (e.g., indium antimonide, gallium antimonide, or indium gallium antimonide) and can be in-situ doped during an epitaxial growth process using p-type dopants, such as boron, indium, and gallium. For p-type in-situ doping, p-type doping precursors, such as diborane (B₂H₆), boron trifluoride (BF₃), and other p-type doping precursors, can be used.

In some embodiments, as shown in FIG. 2, S/D structures 110 can have a height 110h along a Z-axis ranging from about 50 nm to about 80 nm. In some embodiments, S/D structures 110 can have a width 110w along an X-axis ranging from about 20 nm to about 40 nm. In some embodiments, as shown in FIG. 2, S/D structures 110 can include a non-crystalline portion 110A and a crystalline portion 110B. In some embodiments, non-crystalline portion 110A can include a non-crystalline semiconductor material, such as amorphous or poly-crystalline semiconductor material. In some embodiments, non-crystalline portion 110A can be below the bottom surface of bottom nanostructures 122-1. If non-crystalline portion 110A is above the bottom surface of bottom nanostructures 122-1, the size of crystalline portion 110B may be reduced, the strain imparted on the channel regions of nanostructures 122 may be reduced, and the carrier mobility in the channel regions of nanostructures 122 may be decreased. Additionally, if non-crystalline portion 110A is above the bottom surface of bottom nanostructures 122-1, nanostructures 122 may be in contact with non-crystalline portion 110A, device current between nanostructures 122 and S/D structures 110 can be reduced and device performance can be degraded.

In some embodiments, non-crystalline portion 110A can have a thickness 110At along a Z-axis ranging from about 1 nm to about 6 nm. In some embodiments, a ratio between thickness 110At and thickness 122t can range from 0.3 to about 0.7. If thickness 110At is less than about 1 nm or the ratio is less than about 0.3, crystalline portion 110B of S/D structures may become non-crystalline. If thickness 110At is greater than about 6 nm or the ratio is greater than about 0.7, the size of crystalline portion 110B may be reduced, the strain on nanostructures 122 and the carrier mobility in nanostructures 122 may be decreased, non-crystalline portion 110A may be in contact with nanostructures 122, drive current of semiconductor device 100 may be reduced, and device performance of semiconductor device 100 may be degraded.

In some embodiments, crystalline portion 110B of S/D structures 110 can include one or more epitaxial layers, where each epitaxial layer can have different compositions. In some embodiments, each of the one or more epitaxial layers can include Si and differ from each other based on, for example, doping concentration and/or epitaxial growth process conditions. In some embodiments, each of the one or more epitaxial layers can include silicon germanium and differ from each other based on, for example, doping concentration, epitaxial growth process conditions, and/or relative concentration of germanium with respect to silicon.

Referring to FIGS. 1 and 2, ESL 116 can be disposed on S/D structures 110 and sidewalls of gate spacers 114 and sidewall spacers 109. ESL 116 can be configured to protect S/D structures 110, S/D dielectric structures 111, and gate structures 112 during subsequent formation of S/D contact structures 130 on S/D structures 110. In some embodiments, ESL 116 can include, for example, silicon oxide, silicon nitride, silicon oxynitride, silicon carbide, silicon carbonitride, boron nitride, silicon boron nitride, silicon carbon boron nitride, or a combination thereof.

ILD layer 118 can be disposed on ESL 116 over S/D structures 110 and STI regions 106. In some embodiments, ILD layer 118 can include a dielectric material deposited using a deposition method suitable for flowable dielectric materials. For example, flowable silicon oxide can be deposited using flowable chemical vapor deposition (FCVD). In some embodiments, the dielectric material can include silicon oxide.

In some embodiments, as shown in FIGS. 1 and 2, semiconductor device 100 can further include S/D contact structures 130. In some embodiments, S/D contact structures 130 can be disposed on S/D structures 110. In some embodiments, S/D contact structures 130 can include a silicide layer 130A and a metal contact 130B. In some embodiments, silicide layer 130A can include metal silicide and can provide a lower resistance interface between metal contact 130B and S/D structures 110. Examples of metal used for forming the metal silicide include cobalt, titanium, and nickel. In some embodiments, metal contact 130B can include conductive materials, such as tungsten, aluminum, and cobalt. In some embodiments, as shown in FIGS. 1 and 2, S/D contact structures 130 can extend through ILD layer 118 and into S/D structures 110. In some embodiments, top surfaces of gate structures 112, gate spacers 114, ESL 116, ILD layer 118, and S/D contact structures 130 can be coplanar. In some embodiments, semiconductor device 100 can further include metal lines, metal vias, interconnects, and additional ILD layers.

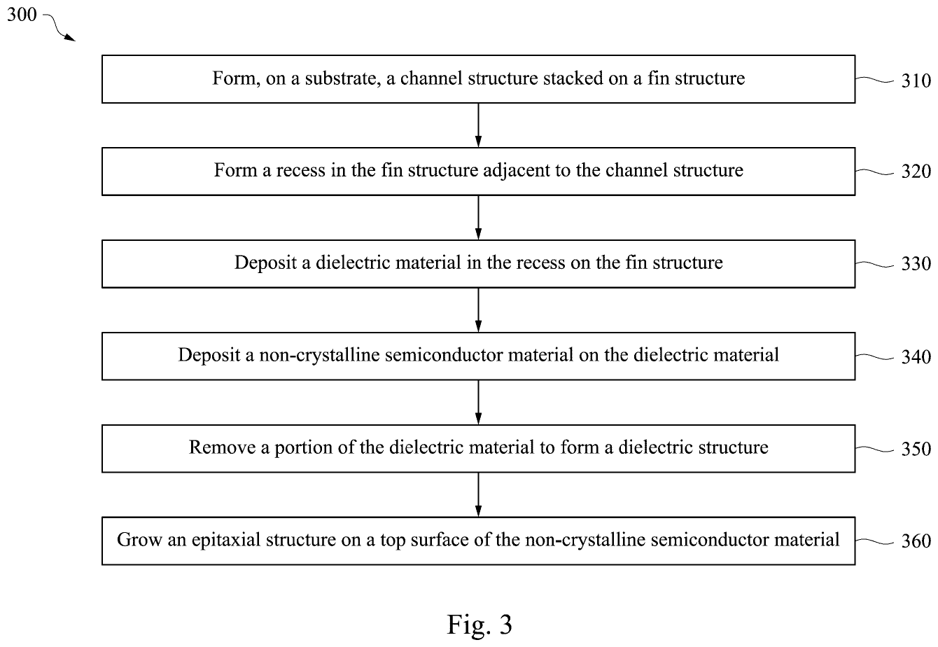

FIG. 3 is a flow diagram of a method 300 for fabricating semiconductor device 100 having a semiconductor seed layer on S/D dielectric structures, in accordance with some embodiments. Method 300 may not be limited to nanostructure transistor devices and can be applicable to other devices that would benefit from the semiconductor seed layer on S/D dielectric structures. Additional fabrication operations may be performed between various operations of method 300 and may be omitted merely for clarity and ease of description. Additional processes can be provided before, during, and/or after method 300; one or more of these additional processes are briefly described herein. Moreover, not all operations may be needed to perform the disclosure provided herein. Additionally, some of the operations may be performed simultaneously or in a different order than shown in FIG. 3. In some embodiments, one or more other operations may be performed in addition to or in place of the presently-described operations.

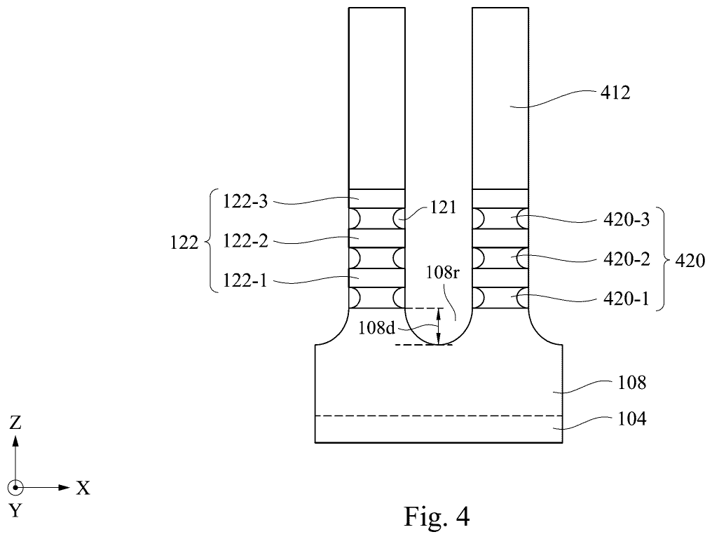

For illustrative purposes, the operations illustrated in FIG. 3 will be described with reference to the example fabrication process for fabricating semiconductor device 100 as illustrated in FIGS. 4-12. FIGS. 4-12 illustrate partial cross-sectional views of semiconductor device 100 along line A-A as shown in FIG. 1 at various stages of its fabrication, in accordance with some embodiments. Elements in FIGS. 4-12 with the same annotations as elements in FIGS. 1 and 2 are described above.

In referring to FIG. 3, method 300 begins with operation 310 and the process of forming, on a substrate, a channel structure stacked on a fin structure. For example, as shown in FIG. 4, nanostructures 122 and nanostructures 420-1, 420-2, and 420-3 (collectively referred to as “nanostructures 420”) stacked on fin structures 108 can be formed on substrate 104. In some embodiments, nanostructures 122 and 420 can be stacked in an alternate configuration. In some embodiments, nanostructures 122 and 420 can be epitaxially grown on substrate 104 and subsequently patterned to form nanostructures 122 and 420 stacked on fin structures 108. In some embodiments, nanostructures 122 and 420 can be in the form of nanosheets, nanowires, or nano-ribbons. In some embodiments, nanostructures 122 and 420 can include semiconductor materials similar to or different from substrate 104. In some embodiments, fin structures 108 can include the same semiconductor material as substrate 104. In some embodiments, nanostructures 122 and 420 can include different semiconductor materials. For example, nanostructures 122 can include silicon, and nanostructures 420 can include silicon germanium with a germanium atomic percentage from about 10% to about 40%.

Embodiments of fin structures 108 and nanostructures 122 and 420 disclosed herein may be patterned by any suitable method. For example, the fin structures and the nanostructures may be patterned using one or more photolithography processes, including double-patterning or multi-patterning processes. Double-patterning or multi-patterning processes can combine photolithography and self-aligned processes, forming patterns that have, for example, pitches smaller than what is otherwise obtainable using a single, direct photolithography process. For example, a sacrificial layer is formed over a substrate and patterned using a photolithography process. Spacers can be formed alongside the patterned sacrificial layer using a self-aligned process. The sacrificial layer is then removed, and the remaining spacers can then be used to pattern the fin structures and the nanostructures.

The formation of nanostructures 122 can be followed by the formation of STI regions 106 between adjacent stacks of nanostructures 122 and 420 and the formation of sacrificial gate structures 412 on nanostructures 122, as shown in FIG. 4.

Referring to FIG. 3, in operation 320, a recess is formed in the fin structure adjacent to the channel structure. For example, as shown in FIG. 4, nanostructures 122 and 420 and fin structures 108 can be recessed to form recess 108r in fin structures 108 adjacent to nanostructures 122 and 420. In some embodiments, recess 108r can extend into fin structures 108 below nanostructures 122 and 420. In some embodiments, as shown in FIG. 4, recess 108r in fin structures 108 can have a concave profile and a depth 108d along a Z-axis ranging from about 4 nm to about 12 nm. In some embodiments, depth 108d can ensure complete removal of bottom nanostructures 420 and formation of S/D dielectric structures 111, semiconductor seed layer 113, and amorphous portion 110A of S/D structures 110 below the bottom surface of bottom nanostructures 122-1.

In some embodiments, the formation of recess 108r can be followed by the formation of inner spacers 121, as shown in FIG. 4. In some embodiments, the formation of inner spacers 121 can include the lateral recess of nanostructures 420, the deposition of a spacer layer, and the trim of the spacer layer.

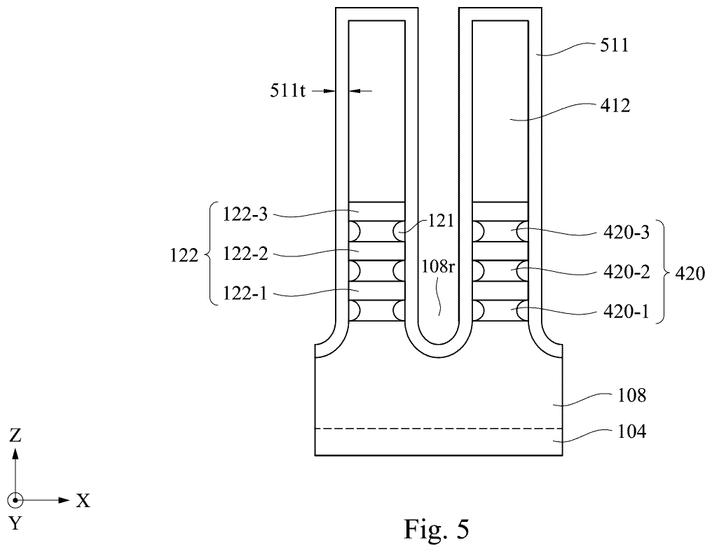

Referring to FIG. 3, in operation 330, a dielectric material is deposited in the recess on the fin structure. For example, as shown in FIG. 5, dielectric material 511 can be deposited in recess 108r on fin structures 108 and on sacrificial gate structures 412. In some embodiments, dielectric material 511 can be conformally deposited on fin structures 108, nanostructures 122, inner spacers 121, and sacrificial gate structures 412. In some embodiments, dielectric material 511 can be deposited by furnace, plasma-assisted atomic layer deposition (plasma-assisted ALD), conformal chemical vapor deposition (conformal CVD), or other suitable deposition method. In some embodiments, dielectric material 511 can include AlOₓ, SiCₓ, SiNₓ, SiCₓN₁₋ₓ, SiO_{y}CₓN_{1-x-y}, a low-k material, or a combination thereof. In some embodiments, dielectric material 511 can have a thickness 511t ranging from about 3 nm to about 5 nm.

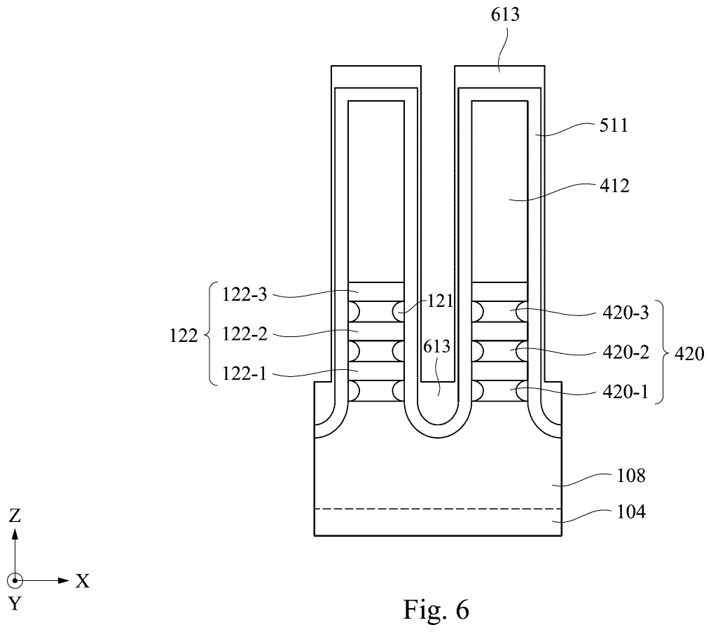

Referring to FIG. 3, in operation 340, a non-crystalline semiconductor material is deposited on the dielectric material. For example, as shown in FIG. 6, non-crystalline semiconductor material 613 can be deposited on dielectric material 511. In some embodiments, non-crystalline semiconductor material 613 can be directionally deposited on dielectric material 511 by furnace, chemical vapor deposition (CVD) with potential bias, or other suitable deposition methods. In some embodiments, non-crystalline semiconductor material 613 can be deposited using a precursor of silane. In some embodiments, non-crystalline semiconductor material 613 can include amorphous or poly-crystalline semiconductor materials. In some embodiments, non-crystalline semiconductor material 613 can include non-crystalline silicon, non-crystalline silicon germanium, or other suitable non-crystalline semiconductor materials. In some embodiments, as shown in FIG. 6, non-crystalline semiconductor material 613 may be mainly deposited on top surfaces of dielectric material 511 and minimally deposited on sidewall surfaces of dielectric material 511.

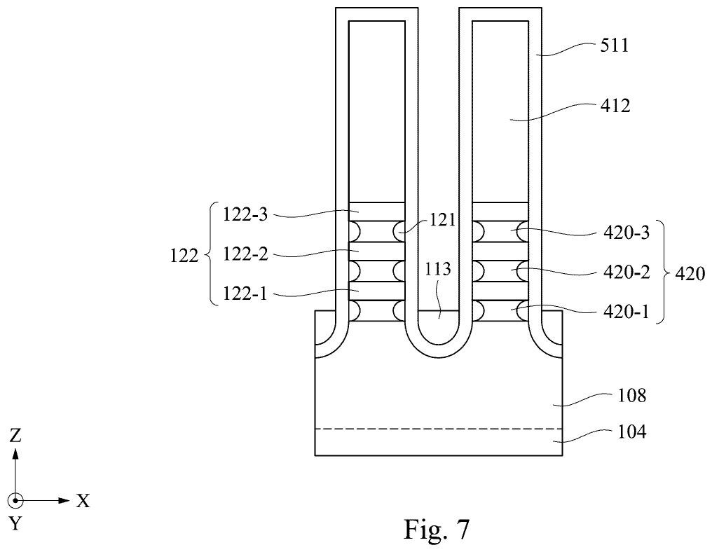

In some embodiments, the deposition of non-crystalline semiconductor material 613 can be followed by etching of non-crystalline semiconductor material 613. For example, as shown in FIG. 7, non-crystalline semiconductor material 613 on sidewall surfaces of dielectric material 511 and on top surfaces of dielectric material 511 above sacrificial gate structures 412 can be removed by an etching process. In some embodiments, the etching process can use etching gases, such as hydrogen plasma and chlorine plasma. In some embodiments, the etching gases may not be able to reach non-crystalline semiconductor material 613 in recess 108r and the remaining non-crystalline semiconductor material 613 in recess 108r can form semiconductor seed layer 113.

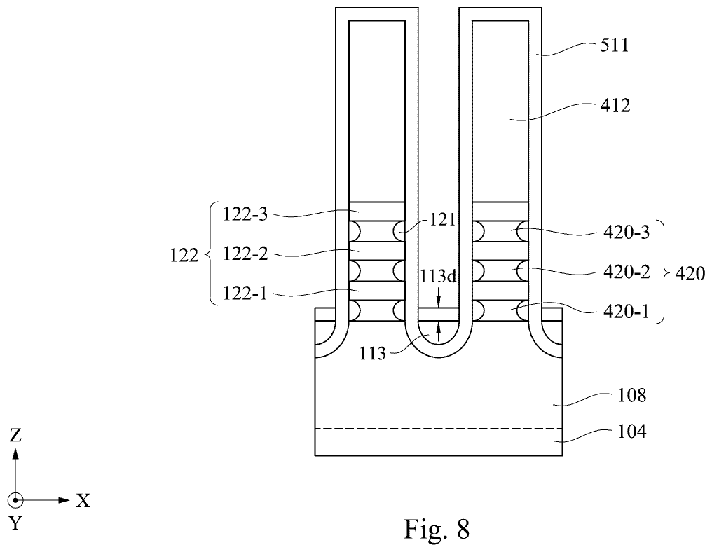

In some embodiments, the etching of non-crystalline semiconductor material 613 can be followed by treating a top portion of semiconductor seed layer 113. For example, as shown in FIG. 8, the top portion of semiconductor seed layer 113 can be oxidized with an oxygen-containing source or nitridized with a nitrogen-containing source. In some embodiments, the top portion of semiconductor seed layer 113 can be oxidized or nitridizded by a plasma process, a thermal process, an implantation process, or other suitable processes. In some embodiments, after the oxidation or nitridation treatment, the top portion of semiconductor seed layer 113 and dielectric material 511 can have a substantially same thickness, a substantially same density, and a substantially same wet etching rate. In some embodiments, as shown in FIG. 8, the top treated portion of semiconductor seed layer can have a thickness 113d along a Z-axis ranging from about 3 nm to about 5 nm.

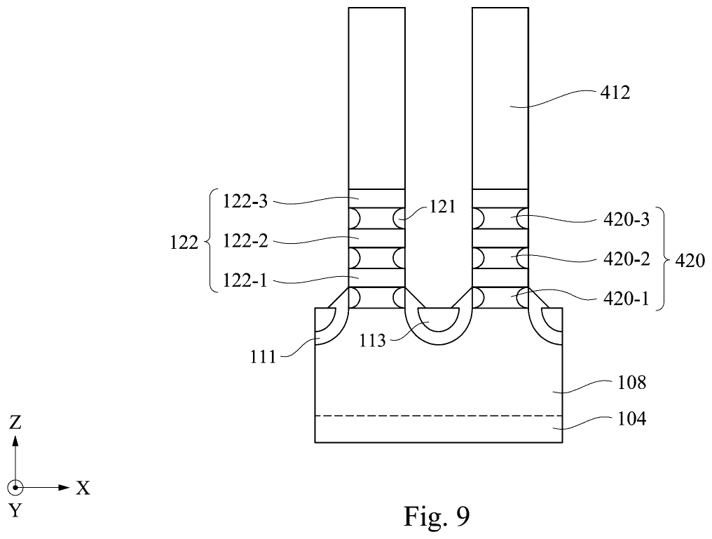

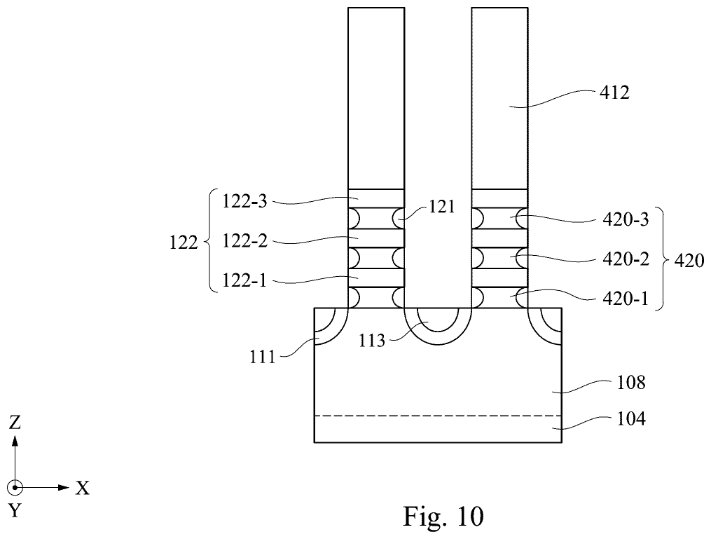

Referring to FIG. 3, in operation 350, a portion of the dielectric material is removed to form a dielectric structure. For example, as shown in FIGS. 9 and 10, a portion of dielectric material 511 on sacrificial gate structures 412, nanostructures 122, and inner spacers 121 can be removed to form S/D dielectric structures 111 and expose top surfaces of semiconductor seed layer 113. In some embodiments, the portion of dielectric materials 511 can be removed by an isotropic etching process. In some embodiments, the isotropic etching process can include nitrogen trifluoride (NF₃) dry etch, phosphoric acid with diluted hydrogen fluoride (H₃PO₄/HF) wet etch, or a dry etch and wet etch integration. In some embodiments, when thickness 113d is greater than thickness 511t, S/D dielectric structures 111 can have a “U” shape and end portions of S/D dielectric structures 111 can be above a top surface of semiconductor seed layer 113 and cover inner spacers 121 below bottom nanostructures 122-1, as shown in FIG. 9. In some embodiments, when thickness 113d is equal to or less than thickness 511t, end portions of S/D dielectric structures 111 can be at the same level or below the top surface of semiconductor seed layer 113, as shown in FIG. 10.

In some embodiments, as shown in FIG. 9, the end portions of S/D dielectric structures 111 can have sloped top surfaces with inner edges of the end portions lower than the outer edges of the end portions. In some embodiments, with end portions of S/D dielectric structures 111 covering inner spacers 121 as shown in FIG. 9, the parasitic capacitance between S/D structures 110 and gate structures 112 can be reduced and device performance can be further improved.

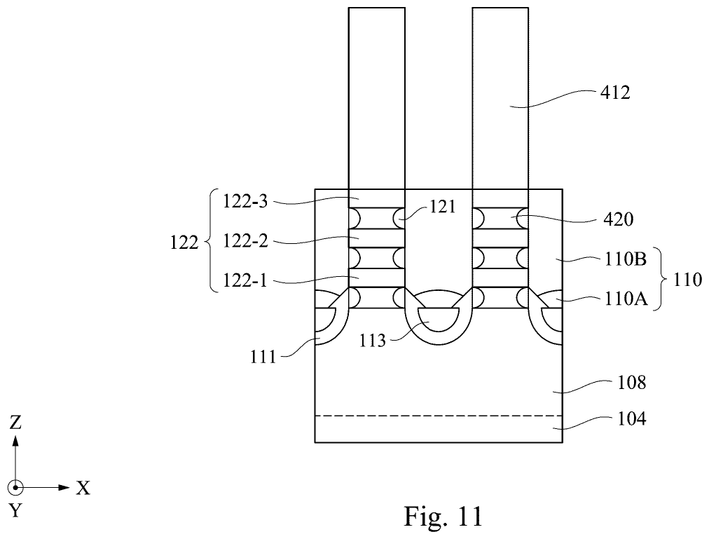

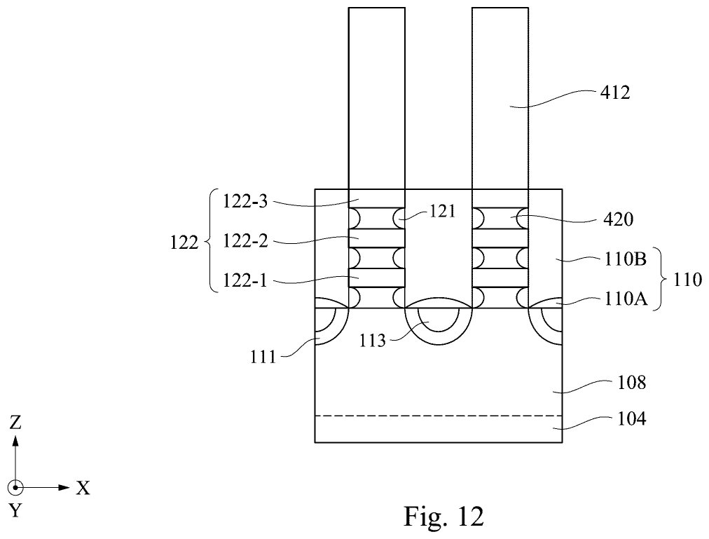

Referring to FIG. 3, in operation 360, an epitaxial structure can be grown on a top surface of the non-crystalline semiconductor material. For example, as shown in FIGS. 11 and 12, S/D structures 110 can be epitaxially grown on top surfaces of non-crystalline semiconductor seed layer 113 and dielectric structures 111 shown in FIGS. 9 and 10, respectively. In some embodiments, as shown in FIGS. 11 and 12, S/D structures 110 can include a non-crystalline portion 110A grown on semiconductor seed layer 113 and S/D dielectric structures 111 and a crystalline portion 110B grown on non-crystalline portion 110B. In some embodiments, non-crystalline portion 110A can include a non-crystalline semiconductor material, such as amorphous or poly-crystalline semiconductor material. In some embodiments, non-crystalline portion 110A can be below the bottom surface of bottom nanostructures 122-1. If non-crystalline portion 110A is above the bottom surface of bottom nanostructures 122-1, the size of crystalline portion 110B may be reduced, the strain imparted on the channel regions of nanostructures 122 may be reduced, and the carrier mobility in the channel regions of nanostructures 122 may be decreased. Additionally, if non-crystalline portion 110A is above the bottom surface of bottom nanostructures 122-1, nanostructures 122 may be in contact with non-crystalline portion 110A, device current between nanostructures 122 and S/D structures 110 can be reduced and device performance can be degraded.

In some embodiments, crystalline portion 110B of S/D structures 110 can include one or more epitaxial layers, where each epitaxial layer can have different compositions. In some embodiments, each of the one or more epitaxial layers can include Si and differ from each other based on, for example, doping concentration and/or epitaxial growth process conditions. In some embodiments, each of the one or more epitaxial layers can include silicon germanium and differ from each other based on, for example, doping concentration, epitaxial growth process conditions, and/or relative concentration of germanium with respect to silicon.

In some embodiments, the formation of S/D structures 110 can be followed by the deposition of ESL 116 and ILD layer 118, the replacement of sacrificial gate structures 412 with metal gate structures 112, and the formation of S/D contact structures 130 on S/D structures 110, as shown in FIG. 2. In some embodiments, the replacement of sacrificial gate structures 412 can include removal of sacrificial gate structures 412, removal of nanostructures 420, and deposition of metal gate structures 112. In some embodiments, after deposition of gate structures 112 and formation of S/D contact structures 130, a CMP process can planarize top surfaces of gate structures 112, gate spacers 114, ESL 116, and ILD layer 118, as shown in FIG. 2.

Various embodiments in the present disclosure provide methods for forming semiconductor seed layer 113 on S/D dielectric structures 111 in semiconductor device 100. In some embodiments, nanostructures 122 stacked on fin structures 108 can be formed on substrate 104. Recess 108r can be formed in fin structures 108 adjacent to nanostructures 122. S/D dielectric structures 111 and semiconductor seed layer 113 can be formed in recess 108r. S/D dielectric structures 111 and semiconductor seed layer 113 can be below the bottom surface of bottom nanostructures 122-1. S/D structures 110 can be formed on top surfaces of S/D dielectric structures 111 and semiconductor seed layer 113. S/D structures 110 can include non-crystalline portion 110A and crystalline portion 110B. Crystalline portion 110B can be in contact with nanostructures 122 and non-crystalline portion 110A can be below the bottom surface of bottom nanostructures 122-1. With S/D dielectric structures 111, semiconductor seed layer 113, and non-crystalline portion 110A of S/D structures 110 below the bottom surface of bottom nanostructures 122-1, resistance between S/D structures 110 and nanostructures 122 can be reduced. The carrier mobility in S/D structures 110 can be increased. The strain on nanostructures 122 exerted by S/D structures 110 can be increased. Accordingly, the DC device performance of semiconductor device 100 can be improved.

In some embodiments, a semiconductor structure includes a channel structure on a substrate, a gate structure wrapped around the channel structure, an inner spacer adjacent to end portions of the gate structure and the channel structure, a dielectric structure on the substrate and adjacent to the inner spacer, a non-crystalline semiconductor material on the dielectric structure, and an epitaxial structure on top surfaces of the non-crystalline semiconductor material and the dielectric structure.

In some embodiments, a semiconductor device includes first and second channel structures stacked on a fin structure and a dielectric structure on the fin structure and between the first and second channel structures. The dielectric structure extends into the fin structure and is below the first and second channel structures. a non-crystalline semiconductor material on the dielectric structure, and a source/drain (S/D) structure on a top surface of the non-crystalline semiconductor material. The S/D structure is adjacent to the non-crystalline semiconductor material and the dielectric structure.

In some embodiments, a method includes forming, on a substrate, a channel structure stacked on a fin structure, forming a recess in the fin structure adjacent to the channel structure, depositing a dielectric material in the recess on the fin structure, depositing a non-crystalline semiconductor material on the dielectric material, removing a portion of the dielectric material to form a dielectric structure, and growing an epitaxial structure on top surfaces of the non-crystalline semiconductor material and the dielectric structure.

It is to be appreciated that the Detailed Description section, and not the Abstract of the Disclosure section, is intended to be used to interpret the claims. The Abstract of the Disclosure section may set forth one or more but not all possible embodiments of the present disclosure as contemplated by the inventor(s), and thus, are not intended to limit the subjoined claims in any way.

The foregoing disclosure outlines features of several embodiments so that those skilled in the art may better understand the aspects of the present disclosure. Those skilled in the art will appreciate that they may readily use the present disclosure as a basis for designing or modifying other processes and structures for carrying out the same purposes and/or achieving the same advantages of the embodiments introduced herein. Those skilled in the art will also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure, comprising:
a channel structure on a substrate;
a gate structure wrapped around the channel structure;
an inner spacer adjacent to end portions of the gate structure and the channel structure;
a dielectric structure on the substrate and adjacent to the inner spacer;
a non-crystalline semiconductor material on the dielectric structure; and
an epitaxial structure on top surfaces of the non-crystalline semiconductor material and the dielectric structure.

2. The semiconductor structure of claim 1, wherein a top surface of the dielectric structure is below a bottom surface of the channel structure.

3. The semiconductor structure of claim 1, wherein a ratio of a thickness of the dielectric structure to a thickness of the channel structure ranges from about 0.2 to about 0.8.

4. The semiconductor structure of claim 1, wherein the epitaxial structure comprises a non-crystalline portion on the non-crystalline semiconductor material and a crystalline portion on the non-crystalline portion.

5. The semiconductor structure of claim 4, wherein a ratio of a thickness of the non-crystalline portion to a thickness of the channel structure ranges from about 0.3 to about 0.7.

6. The semiconductor structure of claim 4, wherein a top surface of the non-crystalline portion is below a bottom surface of the channel structure.

7. The semiconductor structure of claim 1, wherein a distance between a bottom surface of the dielectric structure and a bottom surface of the gate structure ranges from about 4 nm to about 12 nm.

8. The semiconductor structure of claim 1, wherein the dielectric structure comprises aluminum oxide, silicon carbide, silicon carbonitride, silicon nitride, silicon oxycarbonitride, or a low-k dielectric material.

9. The semiconductor structure of claim 1, wherein a ratio of a thickness of the non-crystalline semiconductor material to a thickness of the channel structure ranges from about 0.1to about 0.9.

10. A semiconductor device, comprising:
first and second channel structures stacked on a fin structure;
a dielectric structure on the fin structure and between the first and second channel structures, wherein the dielectric structure extends into the fin structure and is below the first and second channel structures;
a non-crystalline semiconductor material on the dielectric structure; and
a source/drain (S/D) structure on a top surface of the non-crystalline semiconductor material, wherein the S/D structure is adjacent to the non-crystalline semiconductor material and the dielectric structure.

11. The semiconductor device of claim 10, wherein a top surface of the dielectric structure is below bottom surfaces of the first and second channel structures.

12. The semiconductor device of claim 10, wherein a ratio of a thickness of the dielectric structure to a thickness of the channel structure ranges from about 0.2 to about 0.8.

13. The semiconductor device of claim 10, wherein the S/D structure comprises a non-crystalline portion on the non-crystalline semiconductor material and a crystalline portion on the non-crystalline portion.

14. The semiconductor device of claim 13, wherein a ratio of a thickness of the non-crystalline portion to a thickness of the channel structure ranges from about 0.3 to about 0.7.

15. The semiconductor device of claim 13, wherein a top surface of the non-crystalline portion is below a bottom surface of the channel structure.

16. The semiconductor device of claim 10, wherein a distance between a bottom surface of the dielectric structure and a bottom surface of the gate structure ranges from about 4 nm to about 12 nm.

17. A method, comprising:
forming, on a substrate, a channel structure stacked on a fin structure;
forming a recess in the fin structure adjacent to the channel structure;
depositing a dielectric material in the recess on the fin structure;
depositing a non-crystalline semiconductor material on the dielectric material;
removing a portion of the dielectric material to form a dielectric structure; and
growing an epitaxial structure on top surfaces of the non-crystalline semiconductor material and the dielectric structure.

18. The method of claim 17, wherein depositing the dielectric material comprises conformally depositing the dielectric material on the channel structure and the fin structure.

19. The method of claim 17, wherein removing the portion of the dielectric material comprises:
treating a top portion of the non-crystalline semiconductor material to form a dielectric layer; and
etching the dielectric layer on the non-crystalline semiconductor material and the dielectric material on the channel structure to expose the top surface of the non-crystalline material.

20. The method of claim 17, wherein growing the epitaxial structure comprises:
growing a non-crystalline portion on the top surface of the non-crystalline semiconductor material, wherein a top surface of the non-crystalline portion is below a bottom surface of the channel structure; and
growing a crystalline portion on the non-crystalline portion.
